(19) United States
(12) Patent Application Publication
(10) Pub. No.: US 2011/0227113 A1
(43) Pub. Date: Sep. 22, 2011

(54) LEAD FRAME HAVING UL REFLECTIVE COATING

(75) Inventors: CHENG-CHING CHIEN, New Taipei (TW); BEEN-YANG LIAW, New Taipei (TW)

(73) Assignee: HON HAI PRECISION INDUSTRY CO., LTD., New Taipei (TW)

(21) Appl. No.: 13/049,904

(22) Filed: Mar. 17, 2011

(30) Foreign Application Priority Data
Mar. 17, 2010 (TW) 99204639

(51) Int. Cl. H01L 33/60

(52) U.S. Cl. 257/98; 438/27; 257/E33.072

(57) ABSTRACT

A lead frame (100) of a light emitting diode (LED) comprises a housing (2) and a plurality of electrodes (1) arranged in the housing (2). The housing (2) has a cavity (21) with an inner circumferential surface for reflecting light from a LED chip mounted in the cavity (21). The inner circumferential surface is coated with a reflective coat (22) having a plurality of ultraviolet light reflective particles (23).

### BACKGROUNDING OF THE INVENTION

1. Field of the invention

The present invention relates to a lead frame of a light emitting diode (i.e. LED), and more particularly to a lead frame having a reflective surface coated with an ultraviolet light (UL) reflective coat for reflecting UL from a light-emitting chip.

2. Description of the prior art

A conventional lead frame of a light emitting diode (LED) disclosed in U.S. Pat. No. 7,786,492 issued to Omae et al. on Aug. 31, 2010 includes a housing and a plurality of electrode layers formed in the housing. The housing has a cavity with an inner circumferential surface formed into a reflective surface for reflecting light from a LED chip mounted in the cavity. The inner circumferential surface is coated with an anodized aluminum coat for improving reflection efficiency of the light emitted from the LED chip. The housing is formed of a metal material containing aluminum as its main content. The anodized aluminum coat also can prevent the aluminum of the housing from being oxidized by oxygen in air. Moreover, the LED chip emits UL as well as visible light. However, the anodized aluminum coat can not effectively reflect the UL, since UL can penetrate through metal materials. Some typical lead frames which have non-metallic housings are easily aged and damaged by the UL emitted from the LED chip, as the anodized aluminum coat can not protect the housings.

In view of the above, an improved lead frame that overcomes the above-mentioned disadvantages is desired.

### SUMMARY OF THE INVENTION

Accordingly, an object of the present invention is to provide a lead frame having an UL reflective coat.

To fulfill the above-mentioned object, a lead frame of a light emitting diode (LED) comprises a housing and a plurality of electrodes arranged in the housing. The housing has a cavity with an inner circumferential surface for reflecting light from a LED chip mounted in the cavity. The inner circumferential surface is coated with a reflective coat containing a plurality of UL reflective particles. This invention also provides a lead frame comprising a housing which defines a reflective surface coated with an UL reflective coat.

Other objects, advantages and novel features of the invention will become more apparent from the following detailed description when taken in conjunction with the accompanying drawings.

### BRIEF DESCRIPTION OF THE DRAWINGS

FIG. 1 is an assembled, perspective view of a lead frame of a light emitting diode in accordance with a preferred embodiment of the present invention; and

FIG. 2 is a cross sectional view taking along line 2-2 shown in FIG. 1.

### DETAILED DESCRIPTION OF THE PREFERRED EMBODIMENT OF THE INVENTION

Reference will now be made to the drawings to describe the present invention in detail.

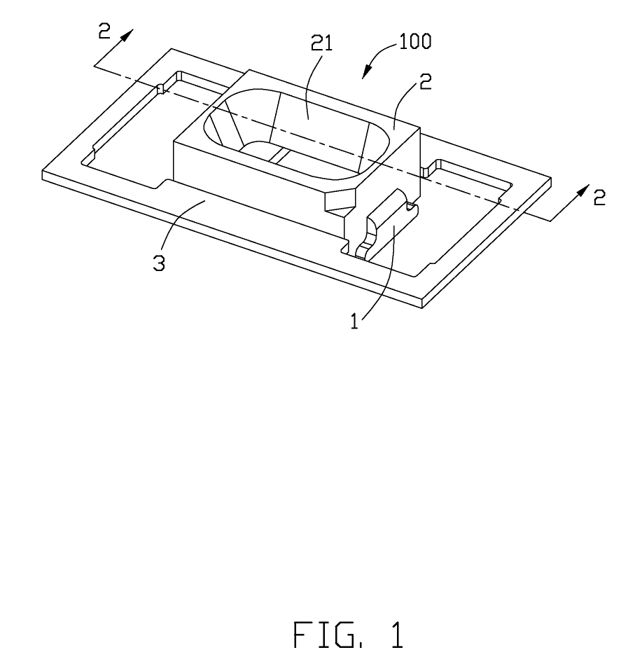

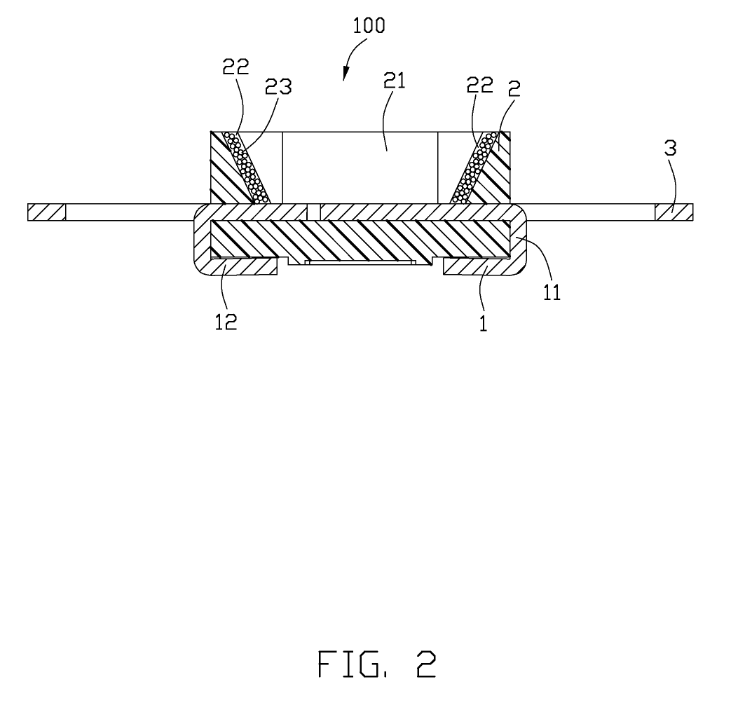

Referring to FIGS. 1 and 2, a lead frame 100 of a light emitting diode (LED) comprises a housing 2 and a pair of electrodes 1 arranged in the housing 2.

The housing 2 is formed of dielectric plastic material and has a cavity 21 with an inner circumferential surface thereof formed into a reflective surface for reflecting light from a LED chip (not shown) mounted in the cavity 21. The inner circumferential surface of the cavity 21 is coated with a reflective coat 22 for reflecting UL. The reflective coat 22 includes a plastic film 22 and a plurality of UL reflective particles 23 admixed therein. The UL reflective particles 23 includes mineral particles. The mineral particles includes anodized titanium particles or/and anodized zinc particles. A particle diameter of each UL reflective particle 23 is between 0.05 μm to 0.1 μm. The UL reflective particles 23 can reflect UL from the LED chip (not shown), thereby preventing the housing 2 from turning yellow and improving reflection efficiency of the light emitted from the LED chip (not shown).

The electrodes 1 electrically connect to the LED chip (not shown) and include a first electrode 11 and a second electrode 12 insulated with each other. One end of each electrode 1 is exposed in the cavity 21 and the other end thereof protrudes out of the housing 1 and extends along an outside wall of the housing 1 to be mounted on a circuit board (not shown). In FIGS. 1 and 2, the electrodes 1 links to a strip 3 which will be detached from the electrodes 1 when the lead frame 100 being used.

While preferred embodiment in accordance with the present invention has been shown and described, equivalent modifications and changes known to persons skilled in the art according to the spirit of the present invention are considered within the scope of the present invention as defined in the appended claims.

What is claimed is:

1. A lead frame of a light emitting diode (LED) comprising:
a housing having a cavity with an inner circumferential surface for reflecting light from a LED chip mounted in the cavity, the inner circumferential surface being coated with a reflective coat having a plurality of ultraviolet light (UL) reflective particles; and
a plurality of electrodes arranged in the housing.

2. The lead frame as claimed in claim 1, wherein the UL reflective particles includes mineral particles.

3. The lead frame as claimed in claim 2, wherein the mineral particles includes anodized titanium particles or anodized zinc particles.

4. The lead frame as claimed in claim 1, wherein a particle diameter of each UL reflective particle is between 0.05 μm to 0.1 μm.

5. The lead frame as claimed in claim 1, wherein the reflective coat comprises a plastic film in which the UL reflective particles are admixed.

6. The lead frame as claimed in claim 1, wherein one end of each electrode is exposed in the cavity and the other end thereof protrudes out of the housing and extends along an outside wall of the housing.

7. A lead frame of a light emitting diode (LED) comprising:
a housing defining a reflective surface for reflecting light from an LED chip, the reflective surface being coated with an ultraviolet light (UL) reflective coat; and
a plurality of electrodes arranged in the housing.

8. The lead frame as claimed in claim 7, wherein the UL reflective coat comprises a plurality of UL reflective particles.

9. The lead frame as claimed in claim 8, wherein the UL reflective particles includes mineral particles.

10. The lead frame as claimed in claim 9, wherein the mineral particles includes anodized titanium particles or anodized zinc particles.

11. The lead frame as claimed in claim 8, wherein a particle diameter of each UL reflective particle is between 0.05 μm to 0.1 μm.

12. The lead frame as claimed in claim 8, wherein the reflective coat comprises a plastic film in which the UL reflective particles are admixed.

13. The lead frame as claimed in claim 7, wherein one end of each electrode is exposed in the cavity and the other end thereof protrudes out of the housing and extends along an outside wall of the housing.

14. A method of making a lead frame for use with an LED (light Emitting Diode), comprising steps of:
a) insert molding an insulative housing with electrodes at a mid level wherein the housing defines a LED receiving cavity upwardly exposed to an exterior with slanted surfaces therein;
b) applying an ultraviolet light (UL) reflective layer on the surfaces.
